(19) United States
(12) Patent Application Publication
(10) Pub. No.: US 2025/0366254 A1
(43) Pub. Date: Nov. 27, 2025

(54) X-RAY DETECTOR WITH SUB-CONTACT DOPING

(71) Applicant: Siemens Healthineers AG, Forchheim (DE)

(72) Inventors: Christian DENKER, Forchheim (DE); Miguel LABAYEN DE INZA, Forchheim (DE); Benedikt Christopher WOLZ, Erlangen (DE); Johannes KIRSCHNER, Hirschaid (DE); Rachid ABDALLAH, Berlin (DE); Bohdan NAHLOVSKYY, Okinawa (JP); Peter SIEVERS, Roettenbach (DE); Robert John ELLWOOD, Okinawa (JP); Jan WREGE, Erlangen (DE)

(73) Assignee: Siemens Healthineers AG, Forchheim (DE)

(21) Appl. No.: 19/215,951

(22) Filed: May 22, 2025

(30) Foreign Application Priority Data
May 23, 2024 (DE) 10 2024 204 760.0

(51) Int. Cl. H10F 77/123; H10F 30/00

(52) U.S. Cl. CPC H10F 77/1233; H10F 30/301

(57) ABSTRACT

An X-ray detector comprises: a semiconductor bulk made of Cd₍₁₋ₓ₎ZnₓTe, wherein x is in a range of 0 to 50%; a contact made of a first material on the semiconductor bulk; and a contact-semiconductor region, which is part of the semiconductor bulk and is adjacent to the contact. The contact-semiconductor region is doped with a second material, which differs from the first material, and a majority of the semiconductor bulk is not doped with the second material.

### CROSS-REFERENCE TO RELATED APPLICATION(S)

The present application claims priority under 35 U.S.C. § 119 to German Patent Application No. 10 2024 204 760.0, filed May 23, 2024, the entire contents of which are incorporated herein by reference.

### FIELD

One or more example embodiments of the present invention relate to an X-ray detector having a semiconductor bulk, a contact on the semiconductor bulk, and a contact-semiconductor region, which is part of the semiconductor bulk and adjacent to the contact. One or more example embodiments of the present invention also relate to a computed tomography apparatus and to a method for producing an X-ray detector.

### BACKGROUND

Independent of the grammatical term usage, individuals with male, female or other gender identities are included within the term.

Photon-counting and energy-resolving CT detectors (computed tomography detectors) consist of a semiconductor layer that absorbs X-ray photons and has metal contacts on the upper face and lower face. The semiconductor can be CdTe or Cd₍₁₋ₓ₎ZnₓTe (x=0-0.5). The metal contact (electrode) facing the X-ray source is normally a continuous layer, whereas the other face is divided into individual pixels in order to achieve spatial resolution. For X-ray detectors that have long-term stability, various contacts, such as ohmic contacts or tunnel contacts, can be used for high photon flux. They are normally produced using physical vapor deposition methods such as electron beam vaporization, sputtering and wet chemical deposition.

The absorption of X-ray photons in a semiconductor leads to generation of charge carriers in the form of electron-hole pairs. The quantity of charge carriers generated per photon increases approximately linearly with the energy of the photon, with a certain statistical variation. A voltage applied to the upper and lower contacts leads to voltage-induced drift by the charge carriers in an opposite direction for holes and electrons to the metal contacts.

Charge carriers are lost on the way to the contacts. This loss depends on the lifetime and mobility of the charge carriers. These lifetimes and mobilities differ between the volume and the near-surface region

An introduction to doping of CdTe is known from A. A. Turturici, J. Franc, R. Grill, V. Dědič, L. Abbene, F. Principato, Electric field manipulation in Al/CdTe/Pt detectors under optical perturbations, Nuclear Instruments and Methods in Physics Research Section A: Accelerators, Spectrometers, Detectors and Associated Equipment, Volume 858, 2017, Pages 36-43, ISSN 0168-9002, https://doi.org/10.1016/j.nima.2017.03.041.

A general overview of CdTe is described in Robert Triboulet, Paul Siffert, “CdTe and Related Compounds; Physics, Defects, Hetero- and Nano-structures, Crystal Growth, Surfaces and Applications”, 1st Edition—Oct. 22, 2009, ISBN: 978008046409.

Two articles by Gnatyuk et al. disclose the diffusing of contact material into a CdTe bulk. The first article, Gnatyuk V, Maslyanchuk O, Solovan M, Brus V, Aoki T: CdTe X/y-ray Detectors with Different Contact Materials, Sensors, 2021; 21(10):3518, (https://doi.org/10.3390/s21103518) relates to a comparative study of surface treatment and contact materials. The second article, Volodymyr Gnatyuk, In/CdTe/Au p-n junction-diode X/y-ray detectors formed by frontside laser irradiation doping, Nuclear Instruments and Methods in Physics Research Section A: Accelerators, Spectrometers, Detectors and Associated Equipment, Volume 1029, 2022, 166397, ISSN 0168-9002, (https://doi.org/10.1016/j.nima.2022.166397) relates to an In/CdTe Schottky contact produced via laser beam diffusion.

Temperature-stable tunnel contacts are known from Saed Thaerion (Redlen), “Low dark current radiation detector and method of making the same”, U.S. Pat. No. 11,378,701B2.

### SUMMARY

An object of one or more example embodiments of the present invention is to improve the stability and lifespan of an X-ray detector.

At least this object is achieved, according to embodiments of the present invention, by an X-ray detector and a production method as claimed in the independent claims. The dependent claims contain advantageous developments of embodiments of the present invention.

Hence according to embodiments of the present invention, an X-ray detector and in particular a computed tomography detector (CT detector for short) having a semiconductor bulk is provided. A computed tomography detector is a specific X-ray detector that has better stability and a shorter response time compared with conventional gamma-ray and X-ray sensors. Furthermore, the computed tomography detector is capable of counting photons especially at high flux rates.

The X-ray detector consists of a semiconductor bulk made of Cd₍₁₋ₓ₎ZnₓTe (cadmium zinc telluride), where x lies in the range of 0 to 50%, and hence constitutes a semiconductor sensor. In the extreme case, the semiconductor bulk can thus consist of just CdTe (cadmium telluride).

Ionizing X-ray radiation generates in the semiconductor bulk charge carriers that can be picked up via contacts on opposite faces of the semiconductor bulk. A first of these contacts is made from a first material and applied on the semiconductor bulk, for instance on an upper face or lower face of the semiconductor bulk. The contact-making for the semiconductor bulk can be performed using standard technology.

In addition, the X-ray detector has a first contact-semiconductor region, which is part of the semiconductor bulk and is directly or indirectly adjacent to the first contact. A region of the semiconductor bulk that is adjacent to the first contact is thus referred to as the first contact-semiconductor region. Preferably, the first contact-semiconductor region is adjacent to an entire face of the first contact. In principle, however, the first contact-semiconductor region can also be adjacent to just part of a face of the first contact. In the case of being indirectly adjacent, an intermediate layer may be provided between the contact and the contact-semiconductor region.

The first contact-semiconductor region is advantageously doped with a second material, which differs from the first material, although the majority of the semiconductor bulk is not doped with the second material. The first contact-semiconductor region therefore has a different doping than the semiconductor bulk. The doping with the second material hence relates to a semiconductor region in the semiconductor bulk, which semiconductor region is close to the first contact. Thus the second material differs from the first material of the first contact. In particular, the second material is hence not the contact material, which has diffused into the semiconductor bulk. As a result of the different materials for the contact and the doping of the near-contact region, additional degrees of freedom are achieved in terms of the parametrization of the CT detector.

Embodiments of the present invention are based on the finding that charge carriers are lost on the way to the contacts. This loss depends on the lifetime and mobility of the charge carriers. These lifetimes and mobilities differ between the volume and the near-surface region. In addition, the barrier at the contact can lead to charging of the near-contact region, thereby reducing the effective field strength that drives the charge carriers to the contacts, which is known as the polarization effect. This effect leads to longer “recovery times” after the absorption of a photon and hence to a reduction in the maximum flux for which each photon signal can be detected independently. Therefore, the charge carrier lifetime and mobility near the contacts, and the contact barrier have a considerable influence on the number of charge carriers detected per photon and on the “recovery time”.

The quantity of detected charge carriers per photon of a specific energy is measured experimentally and used for the energy calibration. This allows losses to be corrected to a certain extent, but variations in these losses lead to variations in the quantity of captured charge carriers for photons of a specific energy. Therefore each change in the charge carrier lifetime and mobility requires a new energy calibration, or can even influence the sensor in such a way that energy calibration is impossible. This means that CTs having long-term stability require sensor properties that are stable in the long-term.

The bulk of such sensors is usually intentionally doped with Cl or with In in order to obtain a semi-insulating material through compensation and hence to lower the dark current. The near-contact region (contact-semiconductor region) in conventional CT detectors has the usual bulk doping, whereas the near-surface region (e.g. laterally between the contacts) is influenced by the cutting, the surface treatment and the contact deposition. This leads to an unintended change in the crystal defect densities, to intrinsic defects such as cadmium vacancies and Te interstitial sites depending on the Cd/Te ratio, and to extrinsic doping by foreign atoms. This is why it is important to select and control as well as possible the parameters of the production steps of cutting, surface treatment and contact deposition. Crystal defect density, intrinsic defects such as cadmium vacancies and Te interstitial sites and the extrinsic doping by foreign atoms can vary over time as a result of temperature-induced, radiation-induced, field-induced and current-induced diffusion, movement or changes in concentration. These variations, as explained above, affect the number of charge carriers detected per photon of a specific energy and require an adjustment to the energy calibration.

Therefore, according to embodiments of the present invention, the near-surface doping is controlled deliberately in order to optimize the contact properties and sensor properties.

According to a specific exemplary embodiment, x, i.e. the proportion of Zn (zinc) with respect to Cd (cadmium), lies in a range of 1 to 15%. Thus the semiconductor bulk is cadmium zinc telluride containing a relatively small percentage of zinc.

In a further exemplary embodiment, the doping with the second material causes a diffusion barrier that impedes diffusion of a given material into the semiconductor bulk. This can curb aging processes that relate to diffusion processes. Furthermore, the diffusion barrier can achieve stabilization of the doping concentrations and of the charge carrier mobility and charge carrier lifetime, or at least masking of effects.

According to another exemplary embodiment, the semiconductor bulk is doped with the second material in such a way that a dark current at field strengths of up to 800 V/mm at the X-ray detector and/or a flat-field response of the X-ray detector changes by less than 10%/year in each case. This can be achieved by a suitable doping concentration or a suitable doping profile and/or dopant. The specific doping ensures that the semiconductor material remains more stable in terms of the detection rate, and, for example, any vacancies are occupied selectively by dopant atoms. It is thereby possible to provide an X-ray detector that is stable for years. The effect of the smaller change can be observed under artificial aging.

In an exemplary embodiment, located on the same face of the semiconductor bulk as the first contact is a further first contact, in spaced relation thereto, and a further first contact-semiconductor region (directly or indirectly) adjacent to the further first contact is doped with the second material or a third material, which differs from the second. The first contacts are laterally separate from each other. For example, the one first contact serves for a first pixel, and the further first contact serves for a second pixel. In principle, the near-contact regions can be doped identically for each pixel. It is also possible, however, to vary the doping of the near-contact regions pixel by pixel. For example, doping gradients in the lateral direction across the pixels could be realized in this way.

According to another exemplary embodiment, located between the first contact-semiconductor region and the further first contact-semiconductor region is an intermediate contact-semiconductor region, which has a different doping than the first contact-semiconductor region and/or the further first contact-semiconductor region. Hence, for example, between the contacts for two neighboring pixels is located an intermediate space that is adjacent to the semiconductor bulk. The semiconductor bulk is thus not covered by a contact in the region between the contacts. A subregion of the semiconductor bulk, which externally is adjacent to the contact intermediate space and, inside the semiconductor bulk, is located between the two first contact-semiconductor regions, can likewise be doped specifically. This doping differs from that of the semiconductor bulk and possibly also from the dopings of the first contact-semiconductor regions. This intermediate contact-semiconductor region can have a separate doping concentration, a separate doping profile and/or a separate dopant, which possibly differ from those of the other contact-semiconductor regions. For example, the intermediate contact-semiconductor region can be optimized in such a way that charge carriers are forced into the contact regions and can hence be captured more easily.

In some cases, the first contact-semiconductor region and the further first contact-semiconductor region have different dopings in terms of material and/or doping profile. It is thereby possible, for example, to give neighboring detector elements different properties. For instance, a detector array can be optimized locally thereby.

In an exemplary embodiment, a second contact is disposed opposite the first contact, for instance on the lower face or upper face of the semiconductor bulk, the semiconductor bulk is located between the first contact and the second contact, and a second contact-semiconductor region adjacent to the second contact is doped differently than the semiconductor bulk with a fourth material. The fourth material can be the same as the second or third material. Alternatively, the fourth material can differ from the second and third material. Hence each of the two opposite contacts on the semiconductor bulk can have a dedicated near-contact contact-semiconductor region that has a doping that differs from the bulk. Hence the contact properties and sensor properties resulting from the second contact can also be optimized.

In an advantageous embodiment, the fourth material differs from the second material for the respective dopings of the contact-semiconductor regions. In principle, the fourth material and the second material can also be the same of course. The variability of the materials means that corresponding degrees of freedom in the design can be employed in the detector optimization.

According to a further exemplary embodiment, it can be provided that on the same face of the semiconductor bulk as the second contact is located in spaced relation thereto a further second contact, and a further second contact-semiconductor region (directly or indirectly) adjacent to the further second contact is doped with the fourth material or a fifth material, which differs from the fourth. The fifth material can be the same as the second or third material. Alternatively, the fifth material can differ from the second and third material. This means that the first contact is located on one face of the semiconductor bulk and the second contacts on an opposite second face of the semiconductor bulk. The second contacts are laterally separate from each other. For example, the one second contact serves for a first pixel, and the further second contact serves for a second pixel. In principle, the near-contact regions can be doped identically for each pixel. It is also possible, however, to vary the doping of the near-contact regions pixel by pixel. For example, doping gradients in the lateral direction across the pixels could be realized in this way.

In a further exemplary embodiment, it can be provided that between the second contact-semiconductor region and the further second contact-semiconductor region is located an intermediate contact-semiconductor region, which has a different doping than the second contact-semiconductor region and/or the further second contact-semiconductor region. Hence, for example, between the contacts for two neighboring pixels is located an intermediate space that is adjacent to the semiconductor bulk. It applies similarly here that the semiconductor bulk is thus not covered by a contact in the region between the contacts. A subregion of the semiconductor bulk, which externally is adjacent to the contact intermediate space and, inside the semiconductor bulk, is located between the two second contact-semiconductor regions, can likewise be doped specifically. This doping differs from that of the semiconductor bulk and possibly also from the dopings of the second contact-semiconductor regions. This intermediate contact-semiconductor region can have a separate doping concentration, a separate doping profile and/or a separate dopant, which possibly differ from those of the other contact-semiconductor regions. For example, the intermediate contact-semiconductor region can be optimized in such a way that charge carriers are forced into the contact regions and can hence be captured more easily.

According to a further exemplary embodiment, the semiconductor bulk is located immediately between the first contact and the second contact. This means that there is no intermediate layer between the contact concerned and the semiconductor bulk. The first and second contacts are thus applied immediately onto the semiconductor bulk. It is thereby possible to capture charge carriers with greater efficiency.

According to an alternative exemplary embodiment, between one or more of the contacts and the associated contact-semiconductor region is disposed a corresponding intermediate layer as a tunnel barrier or for the purposes of temperature stabilization. Optionally, the intermediate layer can also be part of the semiconductor bulk and have a different doping than the contact-semiconductor region. If applicable, however, the intermediate layer is also formed from a different material than the semiconductor bulk or the contact-semiconductor region. Thus further optimizations of the detector can be achieved using the intermediate layer.

In a further exemplary embodiment, the first contact-semiconductor region and the second contact-semiconductor region are doped with different materials. This means that the near-contact contact-semiconductor regions of opposite contacts (first contact and second contact) have different dopings. The first contact and the second contact can also consist of the same or different materials here. This results in numerous doping and material combinations, which in turn can be used for optimizing the detector.

In a further exemplary embodiment, the first contact-semiconductor region and the second contact-semiconductor region have different doping profiles. Thus it is not necessarily required that the first and second contact-semiconductor regions have the same doping profiles perpendicular to the main extension plane of the contacts or perpendicular to the bounding surface of contact and semiconductor bulk. Instead, these doping profiles can be different in particular in this perpendicular direction but also transverse thereto. This results in a further optimization degree of freedom.

In a further exemplary embodiment, it can be provided that the second contact-semiconductor region and the further second contact-semiconductor region have different dopings in terms of material and/or doping profile. This means, for example, that the contact-semiconductor regions, which are assigned to different pixels, are doped with different materials or different doping profiles. Pixel-specific optimizations can be achieved thereby.

According to a further exemplary embodiment, the doping or each doping is performed with a combination of elements. The respective contact-semiconductor regions can consequently be doped with element combinations. Element combinations can also bring about optimization through suitable dopings.

According to a further exemplary embodiment, the contact-semiconductor regions in the semiconductor bulk have a layer thickness of a monolayer up to 300 μm beneath the respective contacts. The layer thickness itself can be an optimization parameter. For example, it is chosen so as to achieve precisely the optimization objective being sought (e.g. temperature stabilization or another property stabilization).

According to an exemplary embodiment, dopants from at least one of the main groups I to V and VII or from the transition metals are used for the doping or the respective dopings. Hence, for example, for a II/VI semiconductor, nearly all the elements can be used for the doping.

According to embodiments of the present invention, an X-ray apparatus or computed tomography apparatus having an X-ray detector or CT detector respectively of the above type can be provided. The computed tomography apparatus has in addition to the CT detector a radiation source, which can move synchronously with the detector, and an analysis unit.

At least the above object is also achieved, according to embodiments of the present invention, by a method for producing an X-ray detector by doping a first contact-semiconductor region, which is part of a semiconductor bulk, with a second material, whereas the majority of the semiconductor bulk is not doped with the second material, and applying a first contact made of a first material, which differs from the second material, onto the first contact-semiconductor region of the semiconductor bulk.

The advantages and possible developments mentioned above in connection with the computed tomography detector apply mutatis mutandis also to the production method. The stated functional features can accordingly be regarded as corresponding method features.

### BRIEF DESCRIPTION OF THE DRAWINGS

The following invention is now explained in more detail with reference to the accompanying drawings, in which:

FIG. 1 shows a schematic cross-section through an X-ray detector according to an exemplary embodiment of the present invention; and

FIG. 2 shows a schematic flow diagram of a method according to an exemplary embodiment of the present invention.

FIG. 3 shows a schematic diagram of an X-ray device according to an embodiment of the present invention.

### DETAILED DESCRIPTION

The exemplary embodiments described in greater detail below constitute preferred embodiments of the present invention.

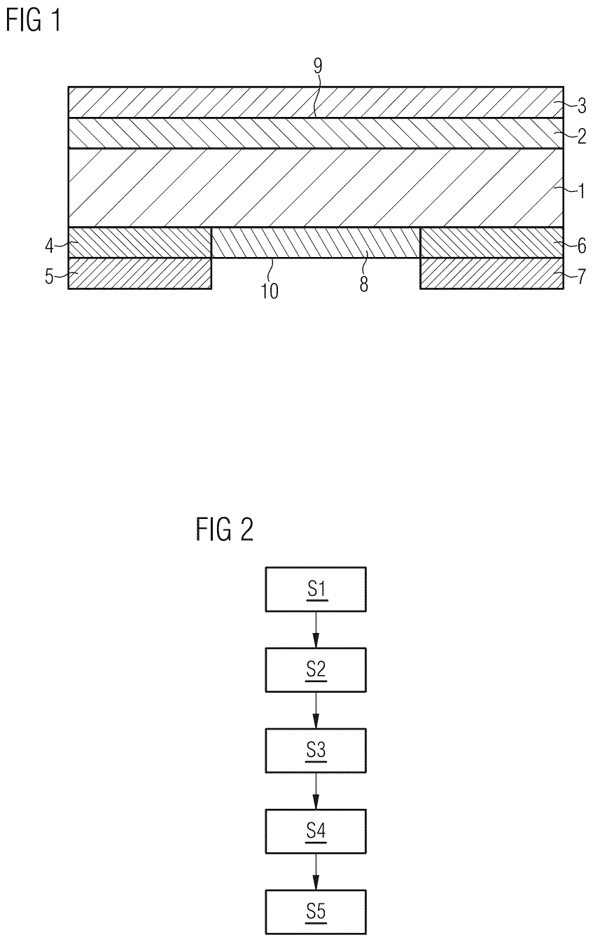

According to the exemplary embodiment of FIG. 1, the X-ray detector shown there has a semiconductor bulk 1. In particular, it is a CdTe or CdZnTe semiconductor, or Cd₍₁₋ₓ₎ZnₓTe, where x lies in the range of 0 to 50%. The semiconductor has an upper face 9 and an opposite lower face 10. On the upper face 9 is a first contact 3. This contact 3 can consist of, for example, platinum, aluminum, indium, tungsten, titanium, gold or other metals and their alloys.

Beneath the upper face 9, the semiconductor bulk 1 has a near-contact first contact-semiconductor region 2. In the present case, this first contact-semiconductor region 2 is immediately adjacent to the first contact 3. The lateral extent of the first contact-semiconductor region 2 here also equals that of the first contact 3. The layer thickness of the first contact-semiconductor region 2 can equal for example, a monolayer up to 300 μm.

In an embodiment, the semiconductor bulk 1 can extend further laterally than the first contact 3. In this case, one or more further first contacts can be located laterally beside the first contact 3 on the surface 9 (array arrangement). Under each of the first contacts is a corresponding first contact-semiconductor region inside the semiconductor bulk 1. These first contact-semiconductor regions can be doped with the same material or with materials that differ from each other. Similarly, also a plurality of the detector elements shown in FIG. 1 can be disposed laterally side by side (each having a separate semiconductor bulk).

Between the first contact-semiconductor region and the further first contact-semiconductor region (not shown in FIG. 1) can be located optionally an intermediate contact-semiconductor region (similar to the intermediate contact-semiconductor region 8 on the lower face 10 of the semiconductor bulk 1 in FIG. 1). This intermediate contact-semiconductor region can have a different doping than the first contact-semiconductor region and/or the further first contact-semiconductor region.

If applicable, the first contact-semiconductor region 2 and the further first contact-semiconductor region have different dopings in terms of material and/or doping profile. Of course, yet another first contact-semiconductor region, which is laterally (directly or indirectly) adjacent, can also have different dopings in terms of material and/or doping profile compared with at least one of the other first contact-semiconductor regions. It is thereby possible, for example, to realize doping gradients in the lateral direction.

If applicable, a second contact 5 is located on the lower face 10 of the semiconductor bulk 1. This second contact 5 can also be a Pt electrode or consist of another material. Above the lower face 10 on top of the second contact 5 is located in the semiconductor bulk 1 a near-contact second contact-semiconductor region 4. The second contact-semiconductor region 4 here has the same lateral extent as the second contact 5. Furthermore, the second contact-semiconductor region 4 is immediately adjacent to the second contact 5.

Optionally, a further second contact 7 is provided on the lower face 10 of the semiconductor bulk 1. The second contact 5 can serve for a first pixel, and the further second contact 7 can serve for a second pixel of the X-ray detector. In the same way as for the second contact 5, also in the case of the further second contact 7 is located thereabove in the semiconductor bulk 1 a near-contact further second contact-semiconductor region 6.

The second contact 5 and the further second contact 7 are in spaced relation to each other on the lower face 10 of the semiconductor bulk 1. Between the two second contacts 5 and 7 is an intermediate contact space, which is not depicted in FIG. 1. Above this intermediate contact space and immediately above the lower face 10 is located in the semiconductor bulk 1 an intermediate contact-semiconductor region 8. Thus in the present example, the contacts 5 and 7 and the regions 4, 6 and 8 are immediately adjacent to the lower face 10. The intermediate contact-semiconductor region 8 is located between the second contact-semiconductor region 4 and the further second contact-semiconductor region 6.

According to embodiments of the present invention, at least one of the contact-semiconductor regions 2, 4, 6, 8 is doped differently than the semiconductor bulk 1. Furthermore, the doping of at least one of the contact-semiconductor regions 2, 4, 6 is performed with a different element or a different element combination than the associated contact 3, 5, 7.

In principle, the dopings on the upper face 9 can be made independently of those on the lower face 10. This means in particular that only on one of the two faces can be provided one or more contact-semiconductor regions of the mentioned type. Specifically, the two faces can also be interchanged, with the result that the mentioned first contacts correspond to the mentioned second contacts, and vice versa. The same applies to the mentioned first and second contact-semiconductor regions.

Advantageously, deliberate and controlled doping of the contact-semiconductor regions 2, 4, 6 and of the intermediate contact-semiconductor region 8 (or just a subset of the semiconductor regions 2, 4, 6, 8) is thus carried out in each case in a layer thickness of a monolayer up to 300 μm and preferably in a layer thickness of 1 to 10 μm. The controlled doping can mask or stabilize the unintended doping in current production steps.

Elements from the main groups I to V and VII and transition metals can be used for the doping. The doping can be performed by ion implantation, thermal and optical diffusion, co-deposition and the like.

This deliberate and controlled near-surface doping, which differs from the doping of the semiconductor bulk 1 of the detector with dopant atoms, improves the control of the contact properties such as barrier height, band alignment and band bending and also charge carrier lifetime and mobility. This reduces the change in the contact properties, resulting in a change in the dark current for fields up to 800 V/mm and in a brightness signal response of less than 10%/year during operation.

In addition to this improvement, the deliberate controlled doping allows an improved time response to bias changes. Furthermore, the doping can guarantee an improved time response to individual photons and to photon flux changes (On/Off and Off/On), which leads to increased linearity of the signal flow response for lower polarization. A higher maximum counter rate can be achieved hereby, which is advantageous in particular for computed tomography detectors.

Furthermore, the deliberate controlled doping can achieve an improved spectral resolution because the various photon energies can be defined more precisely.

In addition, the doping can lead to a reduction in the dark current, the current-induced leakage current and/or noise.

In a further exemplary embodiment is inserted at least between one contact 3, 5, 7 and the associated contact-semiconductor region 2, 4, 6 an intermediate layer, which is not depicted in FIG. 1. This can be a layer of the semiconductor bulk 1 that has a different doping than the corresponding contact-semiconductor region or a layer made of another material. This additional intermediate layer can act as a tunnel barrier or be used for temperature stabilization.

FIG. 2 shows an exemplary embodiment of a method, according to embodiments of the present invention, with reference to a flow diagram. In a first step S1, doping of a first contact-semiconductor region is performed. In an optional step S2, doping of a second contact-semiconductor region is performed. In a further optional step S3, an intermediate contact-semiconductor region can be doped. The steps S1 to S3 can be carried out simultaneously or successively.

In a subsequent step S4, a first contact is applied to the first contact-semiconductor region of the semiconductor bulk. If applicable, a second contact is provided, which is applied to the second contact-semiconductor region in a step S5. Again, these contact-making steps S4 and S5 can be carried out simultaneously or successively.

If applicable, for further pixels of the X-ray detector or computed tomography detector are applied further contacts to corresponding contact-semiconductor regions of the semiconductor bulk.

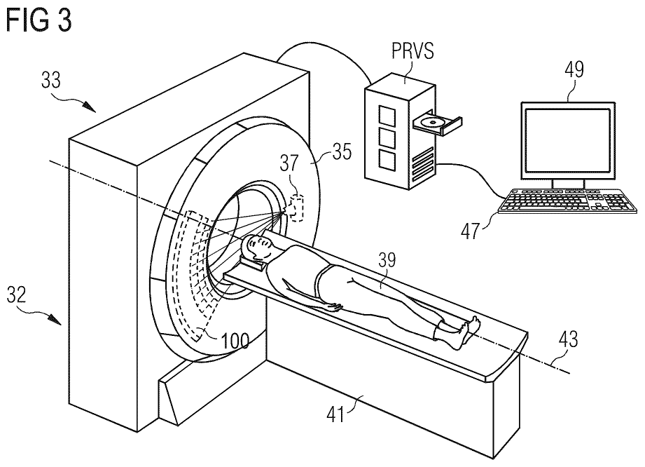

FIG. 3 shows a schematic diagram of an embodiment of an X-ray device as a medical CT device 33. The CT device 33 includes the X-ray source 37, an X-ray detector 100 and a processing unit PRVS. In this figure the X-ray source 37 and the X-ray detector 100 are arranged opposite one another. The X-ray source 37 may be configured to illuminate the X-ray detector 100 with X-ray radiation in a direction of incident X-ray radiation. The X-ray detector 100 may be the X-ray detector shown and described with regard to FIG. 1.

The CT device 33 may further include a gantry 32 with a rotor 35. The X-ray source 37 and the X-ray detector 100 may be arranged in a defined arrangement on the rotor 35, in particular integrated into the rotor 35 or attached to the rotor 35. The rotor 35 may be supported rotatably about an axis of rotation 43. The examination object 39 to be imaged may be supported on the patient support apparatus 41 and be able to be moved along the axis of rotation 43 through the gantry 32. The processing unit PRVS may be used to control the CT device 33 and to calculate slice images or volume images of the examination object 39. An input device 47, for example a keyboard, and an output device 49, for example a screen and/or display, may be connected to the processing unit PRVS for signaling purposes. The input device 47 may be integrated into the output device 49, for example into a resistive and/or capacitive input display. The output device 49 may be configured to display a graphical representation of counting signals and/or of the X-ray image dataset.

The drawings are to be regarded as being schematic representations and elements illustrated in the drawings are not necessarily shown to scale. Rather, the various elements are represented such that their function and general purpose become apparent to a person skilled in the art. Any connection or coupling between functional blocks, devices, components, or other physical or functional units shown in the drawings or described herein may also be implemented by an indirect connection or coupling. A coupling between components may also be established over a wireless connection. Functional blocks may be implemented in hardware, firmware, software, or a combination thereof.

It will be understood that, although the terms first, second, etc. may be used herein to describe various elements, components, regions, layers, and/or sections, these elements, components, regions, layers, and/or sections, should not be limited by these terms. These terms are only used to distinguish one element from another. For example, a first element could be termed a second element, and, similarly, a second element could be termed a first element, without departing from the scope of embodiments. As used herein, the term “and/or,” includes any and all combinations of one or more of the associated listed items. The phrase “at least one of” has the same meaning as “and/or”.

Spatially relative terms, such as “beneath,” “below,” “lower,” “under,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below,” “beneath,” or “under,” other elements or features would then be oriented “above” the other elements or features. Thus, the example terms “below” and “under” may encompass both an orientation of above and below. The device may be otherwise oriented (rotated 90 degrees or at other orientations) and the spatially relative descriptors used herein interpreted accordingly. In addition, when an element is referred to as being “between” two elements, the element may be the only element between the two elements, or one or more other intervening elements may be present.

Spatial and functional relationships between elements (for example, between modules) are described using various terms, including “on,” “connected,” “engaged,” “interfaced,” and “coupled.” Unless explicitly described as being “direct,” when a relationship between first and second elements is described in the disclosure, that relationship encompasses a direct relationship where no other intervening elements are present between the first and second elements, and also an indirect relationship where one or more intervening elements are present (either spatially or functionally) between the first and second elements. In contrast, when an element is referred to as being “directly” connected, engaged, interfaced, or coupled to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of the embodiments. As used herein, the singular forms “a,” “an,” and “the,” are intended to include the plural forms as well, unless the context clearly indicates otherwise. As used herein, the terms “and/or” and “at least one of” include any and all combinations of one or more of the associated listed items. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list. Also, the term “example” is intended to refer to an example or illustration.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which embodiments belong. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

It is noted that some embodiments may be described with reference to acts and symbolic representations of operations (e.g., in the form of flow charts, flow diagrams, data flow diagrams, structure diagrams, block diagrams, etc.) that may be implemented in conjunction with units and/or devices discussed above. Although discussed in a particularly manner, a function or operation specified in a specific block may be performed differently from the flow specified in a flowchart, flow diagram, etc. For example, functions or operations illustrated as being performed serially in two consecutive blocks may actually be performed simultaneously, or in some cases be performed in reverse order. Although the flowcharts describe the operations as sequential processes, many of the operations may be performed in parallel, concurrently or simultaneously. In addition, the order of operations may be re-arranged. The processes may be terminated when their operations are completed, but may also have additional steps not included in the figure. The processes may correspond to methods, functions, procedures, subroutines, subprograms, etc.

Specific structural and functional details disclosed herein are merely representative for purposes of describing embodiments. The present invention may, however, be embodied in many alternate forms and should not be construed as limited to only the embodiments set forth herein.

What is claimed is:

1. An X-ray detector comprising:
a semiconductor bulk made of Cd₍₁₋ₓ₎ZnₓTe, wherein x is in a range of 0 to 50%;
a first contact on the semiconductor bulk, the first contact made of a first material; and
a first contact-semiconductor region, which is part of the semiconductor bulk and is directly or indirectly adjacent to the first contact; wherein
the first contact-semiconductor region is doped with a second material, which differs from the first material, and
a majority of the semiconductor bulk is not doped with the second material.

2. The X-ray detector as claimed in claim 1, wherein x is in a range of 1 to 15%.

3. The X-ray detector as claimed in claim 1, wherein doping with the second material causes a diffusion barrier that impedes diffusion of a given material into the semiconductor bulk.

4. The X-ray detector as claimed in claim 1, wherein the semiconductor bulk is doped with the second material such that at least one of a dark current at field strengths of up to 800 V/mm at the X-ray detector or a flat-field response of the X-ray detector changes by less than 10% per year in each case.

5. The X-ray detector as claimed in claim 1, further comprising:
a further first contact located on a same face of the semiconductor bulk as the first contact; and
a further first contact-semiconductor region adjacent to the further first contact, the further first contact-semiconductor region being doped with the second material or a third material, which differs from the second material.

6. The X-ray detector as claimed in claim 5, further comprising:
an intermediate contact-semiconductor region located between the first contact-semiconductor region and the further first contact-semiconductor region; wherein
the intermediate contact-semiconductor region has a different doping than at least one of the first contact-semiconductor region or the further first contact-semiconductor region.

7. The X-ray detector as claimed in claim 5, wherein the first contact-semiconductor region and the further first contact-semiconductor region have different dopings in terms of at least one of a material or a doping profile.

8. The X-ray detector as claimed in claim 1, further comprising:
a second contact disposed opposite the first contact, wherein the semiconductor bulk is located between the first contact and the second contact; and
a second contact-semiconductor region adjacent to the second contact, the second contact-semiconductor region being doped differently than the semiconductor bulk with a fourth material.

9. The X-ray detector as claimed in claim 8, wherein the fourth material differs from the second material.

10. The X-ray detector as claimed in claim 8, wherein the semiconductor bulk is located immediately between the first contact and the second contact.

11. The X-ray detector as claimed in claim 1, wherein, between the first contact and the first contact-semiconductor region, an intermediate layer is disposed as a tunnel barrier or for temperature stabilization.

12. The X-ray detector as claimed in claim 8, wherein the first contact-semiconductor region and the second contact-semiconductor region are doped with different materials.

13. The X-ray detector as claimed in claim 8, wherein the first contact-semiconductor region and the second contact-semiconductor region have different doping profiles.

14. The X-ray detector as claimed in claim 1, wherein a doping of at least one of the first contact-semiconductor region or the semiconductor bulk is performed with a combination of elements.

15. The X-ray detector as claimed in claim 1, wherein the first contact-semiconductor region has a layer thickness of a monolayer up to 300 μm beneath the first contact.

16. The X-ray detector as claimed in claim 1, wherein the X-ray detector is a computed tomography detector.

17. An X-ray apparatus having an X-ray detector as claimed in claim 1.

18. A method for producing an X-ray detector, the method comprising:
doping a first contact-semiconductor region with a second material, the first contact-semiconductor region being part of a semiconductor bulk made of Cd₍₁₋ₓ₎ZnₓTe, wherein x is in a range of 0 to 50%, and a majority of the semiconductor bulk is not doped with the second material; and
applying a first contact to the first contact-semiconductor region, the first contact being made of a first material, which differs from the second material.

19. The X-ray detector as claimed in claim 2, further comprising:
a further first contact located on a same face of the semiconductor bulk as the first contact; and
a further first contact-semiconductor region adjacent to the further first contact, the further first contact-semiconductor region being doped with the second material or a third material, which differs from the second material.

20. The X-ray detector as claimed in claim 6, wherein the first contact-semiconductor region and the further first contact-semiconductor region have different dopings in terms of at least one of a material or a doping profile.
